(19) United States
(12) Patent Application Publication
(10) Pub. No.: US 2013/0027035 A1
(43) Pub. Date: Jan. 31, 2013

(54) METHOD FOR RECORDING MAGNETIC RESONANCE DATA WITH A MAGNETIC RESONANCE FACILITY

(71) Applicants: Björn HEISMANN, Erlangen (DE); Sebastian SCHMIDT, Weisendorf (DE); Markus VESTER, Nurnberg (DE)

(72) Inventors: Björn HEISMANN, Erlangen (DE); Sebastian SCHMIDT, Weisendorf (DE); Markus VESTER, Nurnberg (DE)

(21) Appl. No.: 13/552,700

(22) Filed: Jul. 19, 2012

(30) Foreign Application Priority Data
Jul. 26, 2011 (DE) 10 2011 079 832.3

(51) Int. Cl. G01R 33/54; G01R 33/32; G01R 33/56

(52) U.S. Cl. 324/307; 324/318

(57) ABSTRACT

A method for recording magnetic resonance data with a magnetic resonance facility is proposed. Protons and sodium are excited. A proton magnetic resonance data record and a sodium magnetic resonance data record are recorded. The proton magnetic resonance data and the sodium magnetic resonance data are recorded during a single recording process.

### CROSS REFERENCE TO RELATED APPLICATIONS

This application claims priority of German application No. 10 2011 079 832.3 filed Jul. 26, 2011, which is incorporated by reference herein in its entirety.

### FIELD OF INVENTION

The application relates to a method for recording magnetic resonance data with a magnetic resonance facility, wherein both protons and also sodium are excited and a proton magnetic resonance data record and a sodium magnetic resonance data record are recorded.

### BACKGROUND OF INVENTION

Sodium imaging is already known as a branch of magnetic resonance research. It is deemed of interest primarily in respect of clinical problems, since numerous indications are associated with an increased sodium concentration in the skin or in a muscle. Nevertheless some problems exist in the field of sodium imaging.

Sodium imaging therefore provides a comparably weak signal so that a minimal signal-to-noise ratio exists. This usually results in a relatively poor spatial resolution of sodium magnetic resonance data records. Voxels are usual for instance, the edge length of which amounts to 3 mm. Consequently, proton magnetic resonance data based on proton signals is needed for the precise anatomical assignment of the sodium magnetic resonance data.

In this context, it is known to sequentially implement a sodium imaging and a proton imaging one after the other. Problems primarily occur here on account of the patient movement and the overall measurement time. On the one hand precise anatomical assignments are extremely difficult and the clinical usability declines on account of the increase in measurement time.

### SUMMARY OF INVENTION

The object therefore underlying the application is to specify a possibility of achieving quicker recording times and an improved spatial assignment in the case of combined proton and sodium imaging recordings.

In order to achieve this object, provision is made in accordance with the application in a method of the type cited in the introduction for the proton magnetic resonance data and the sodium magnetic resonance data to be recorded during a single recording process.

In accordance with the application it is therefore proposed to no longer provide two consecutive recording processes but instead to use one single recording process so that the proton magnetic resonance data and the sodium magnetic resonance data are ultimately recorded in the broader sense “at the same time”, in respect of the movement state of the object to be recorded. Sodium and proton signals can be measured in a single recording process on account of the different resonance frequencies, wherein the gyromagnetic moment lies at 42.6 MHz/T for protons and at 11.2 MHz/T for sodium.

In this way it is basically conceivable in a first embodiment of the method for the proton magnetic resonance data and the sodium magnetic resonance data to be recorded in alternate recording cycles, with a recording cycle for proton magnetic resonance data and sodium magnetic resonance data during a repetition cycle in each instance. This means that the magnetic resonance signals of the two frequencies can be recorded temporally interleaved. In doing so the protons are initially excited in each repetition interval (TR) and the corresponding signal is received, whereby the sodium core is excited and the corresponding signal is received. This is nevertheless likewise advantageous in that patient movements essentially act identically on both magnetic resonance data records, but it is nevertheless disadvantageous that the overall duration of the receive interval which is decisive of the signal-to-noise ratio has to be divided between the two frequencies.

Provision is therefore made in an embodiment of the present application for the proton magnetic resonance data and sodium magnetic resonance data to be recorded in parallel, wherein excitation pulses and receive times are essentially conveyed at the same time. A complete simultaneity of the excitations and the receive times is provided here, wherein reference should be made here to the concept “essentially conveyed at the same time” intelligibly being applied by the person skilled in the art to the possibilities of the technical realization, with respect to the performance of the electronic system when generating the excitation signals. Provision can be made for instance for the excitation pulses and/or the receive times to be maximally offset by a millisecond. In this variant of the method, not only one case which is given, in which the movements act identically on both signal types, but instead no division of the receive time must be performed on account of the parallel data recording so that an acceptable signal-to-noise ratio can also be obtained.

Provision can expediently be made here for a receive coil comprising a double-resonant receive coil or a coil element for sodium and protons, such as in layers arranged one above the other, to be used to receive the magnetic resonance data. It is here to use a double-resonant wired receive coil so that the same coil element can be used for both frequencies. It is however also conceivable to arrange separate coil elements on overlapping shells for instance.

At least one local coil to be arranged on a patient is used as a transmit coil and/or receive coil. The object to be recorded, such as a patient to be recorded, is therefore equipped with a combined sodium and proton receive coil so that measurements can be taken as close as possible to the source of the magnetic resonance signals. If a body coil plugged into the magnetic resonance facility was used to receive the magnetic resonance signals, a lower signal-to-noise ratio would be expected. It has proven to obtain a higher signal-to-noise ratio precisely in terms of the sodium imaging. The transmit function may optionally be integrated here into the local coil or take place by way of the body coil which is fixedly installed in the magnetic resonance facility.

The sodium cores and the protons are therefore excited (essentially) at the same time within the measuring sequence. Provision can be made here for the same gradient pulses to be used for both core types so that the gradient elements of the sequence act on both spin ensembles. Furthermore, provision can be made for inversion pulses and/or spoilers for protons and sodium to be sent essentially at the same time.

In a further embodiment of the present application, provision can be made for different readout channels to be used for the proton magnetic resonance data and the sodium magnetic resonance data or for a bandwidth selection to take place for the simultaneous acquisition of the proton magnetic resonance data and the sodium magnetic resonance data. A separate readout channel can therefore be provided in each instance for both frequency bands, it is alternatively conceivable to realize a bandwidth selection for the simultaneous acquisition of both frequency bands.

In the event that a corresponding number of receive coil elements are provided for the sodium magnetic resonance data and the proton magnetic resonance data in each instance, provision can be made for an accelerated parallel receive technology, such as SENSE or GRAPPA, to be sent. It is to this end similarly also conceivable to use a multichannel transmit technology for both core types, such as at the same time. A further acceleration of the imaging can be achieved in this way.

As already mentioned, provision can be made for the same flow of the same gradient pulse to be used during the recording of the proton magnetic resonance data and sodium magnetic resonance data. This can also be provided in the exemplary embodiment provided at the start, wherein a temporally interleaved recording takes place in order to simplify the overall flow and obtain data which can be compared more easily.

In an embodiment of the present application, provision can be made for a spatial calibration to be implemented for a subsequent shared evaluation of the proton magnetic resonance data record and of the sodium magnetic resonance data record, such as with the aid of a measurement on a phantom. In order to achieve a correct anatomical assignment of the anatomy known from the proton magnetic resonance data to the sodium magnetic resonance data, it must be ensured that a known assignment of the voxel to the two magnetic resonance data records exists, wherefore a calibration for obtaining calibration data is implemented. The assignment of the K-space values to specific sites for both magnetic resonance data records is then known, since, on account of the different resonance frequencies, a factor with respect to the K-space values exists. A phantom calibration is performed here, wherein a corresponding phantom can obtain a sodium pattern and suchlike for instance.

In respect of a clinical evaluation of the recorded magnetic resonance data, an overall data record is determined and indicated by superimposing the proton magnetic resonance data record and the sodium magnetic resonance data record. In this way, on account of the calibration, variations in the sodium concentration can be assigned in a precisely localized fashion to the details of the anatomy which are shown in high resolution. A higher diagnostic reliability is consequently achieved.

Provision can be made here in a further embodiment of the application for the proton magnetic resonance data to be shown in gray scale values in the overall data record, wherein the sodium magnetic resonance data are superimposed onto the proton magnetic resonance data in a color and/or at least partially transparent representation. It is therefore possible to represent the proton magnetic resonance data in black and white for instance, as is basically known, and to add the sodium magnetic resonance data thereto in a colored, sufficiently transparent superimposition. An image which is simple to understand and can be intuitively acquired is produced in this way.

It should be noted again at this point that if the same time curve of the basic field gradients acts on both core types, on account of the gyromagnetic ratio of the sodium spin ensemble which is approximately four times as small, as already mentioned with respect to the calibration, the K-space scanning is nevertheless similar to both measurement data records, the local frequencies are however scaled down by a factor 4 for the sodium. This means that the sodium magnetic resonance data record has a spatial resolution which is reduced approximately four times. It should be noted at this point that the increase in the voxel volume, which is associated therewith, is in line with the already discussed limited signal-to-noise ratio of the sodium measurement by a factor 64, this means that it is in any case meaningful for the sodium magnetic resonance data to make larger voxel sizes, which ultimately result “automatically” in the case of the simultaneous recording.

In this context, in a development of the method, provision can furthermore be made for the sodium magnetic resonance data to be interpolated, such as by splines, such that an interpolated sodium magnetic resonance data record can be determined with the same local resolution as the proton magnetic resonance data record and can form the basis of the superimposition. The sodium magnetic resonance data record is consequently extrapolated to the local resolution of the proton magnetic resonance data record, wherein spline functions are used for interpolation, which allows for the resolution to be increased. This improves the overall impression of the overall data record shown, wherein a robust method is consequently provided, since, as shown above, the data is finally recorded optimized to the signal-to-noise ratio.

All in all, the method therefore provides for improvements in respect of the recording time, the interference by movements and in respect of clinical value, so that the method provides for improved usability in the medical sector.

The data recording can be realized for instance by a correspondingly embodied magnetic resonance facility, wherein the corresponding recording sequences can be controlled for instance by a central control facility of the magnetic resonance facility in accordance with the method. The evaluation steps described, with respect to the superimposition, can be automatically implemented within a magnetic resonance facility, by the control facility. In this way the magnetic resonance facility may include in local coils, which can be arranged on a patient and are suited to the parallel recording of sodium magnetic resonance data and proton magnetic resonance data comprising double-resonant coil elements.

### BRIEF DESCRIPTION OF THE DRAWINGS

Details of the present application result from the exemplary embodiments are described below and with the aid of the drawing, in which:

FIG. 1 shows a flow chart of the method, and

FIG. 2 shows a schematic diagram of a magnetic resonance facility.

### DETAILED DESCRIPTION OF INVENTION

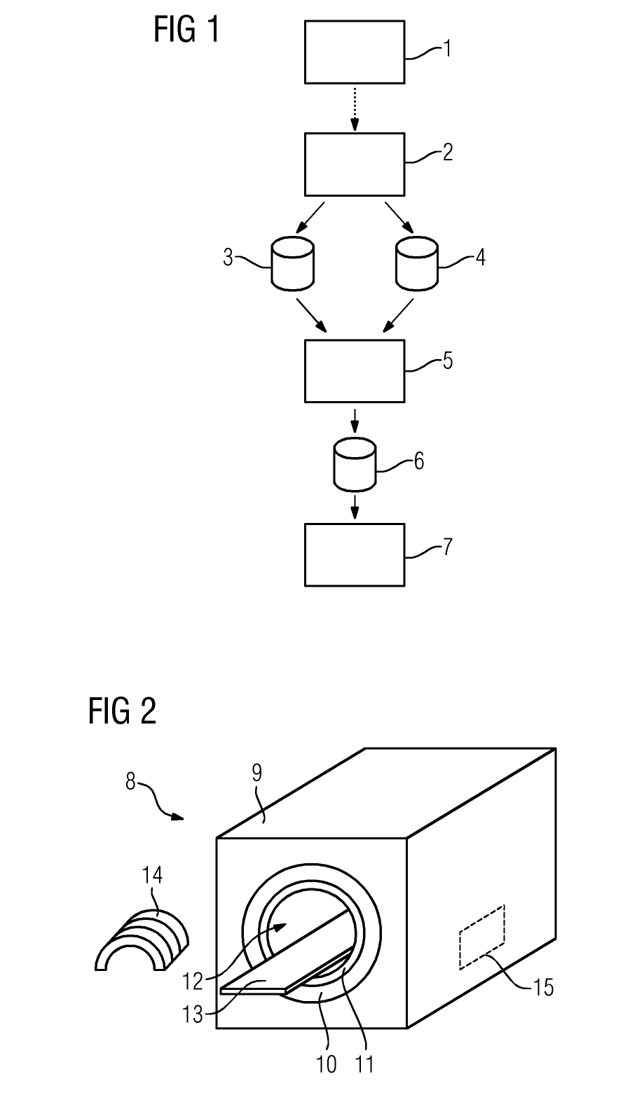

FIG. 1 shows a flowchart of the method, with which proton magnetic resonance data and sodium magnetic resonance data are to be recorded during a single recording process.

A calibration initially takes place in step 1 prior to a concrete recording process, consequently not temporally correlated closely herewith. The calibration is used to adjust the K-space values for the sodium magnetic resonance data and the proton magnetic resonance data to one another so that voxels in the sodium magnetic resonance data record have to be uniquely assigned to voxels in the proton magnetic resonance data record. This is meaningful for both core types on account of the different K-space scanning. A phantom is currently used, from which proton magnetic resonance data and sodium magnetic resonance data are recorded in each instance. These are then adjusted to one another on account of special properties of the phantom which can be found in the data, so that the desired assignment can be determined. For a concrete recording of a sodium magnetic resonance data record and of a proton magnetic resonance data record, a parallel recording of proton magnetic resonance data and sodium magnetic resonance data then takes place in the exemplary embodiment shown here in a step 2, which means that excitation pulses and receive times are used simultaneously (at least within the scope of technical possibilities). The measuring sequence excites the sodium cores and the protons essentially at the same time, wherein the gradient elements of the measuring sequence act on both spin ensembles, which means that on account of the parallel processes, the same flow of the same gradient pulse naturally underlies both measurements. Inversion pulses and spoilers are also sent essentially at the same time for both spin ensembles. The proton signals and the sodium signals are then similarly recorded (essentially) at the same time in a receive time frame.

Provision is made for this purpose to provide the patients with a combined sodium and proton receive local coil, wherein the coil elements are wired in a double-resonant manner in the manner known in the prior art, so that the same coil element can be used for both frequencies. The local coil can also be used for transmission purposes. It is however also possible to use the body coil which is usually permanently installed in the magnetic resonance facility.

Reference should be made to it also naturally being conceivable to provide separate coil elements for both core types instead of local coils which can be wired in a double-resonant manner, it then being possible to arrange the latter on overlapping shells for instance. An (essentially) simultaneous recording of the proton magnetic resonance data and the sodium magnetic resonance data is possible in both instances during the receive time frame.

It is both conceivable to provide a separate readout channel for both frequency bands respectively and also to realize a broadband selection in order to acquire both frequency bands at the same time.

It should be noted again at this point that it would in principle also be conceivable, to record the magnetic resonance signals of the two frequencies in a temporally interleaved manner, wherein the protons in each repetition interval are initially excited and their signals received, whereupon this is performed for the sodium cores.

Reference should also be made, if different coil elements are provided for both frequencies or core types, for instance arranged in several layers one above the other, for SENSE or GRAPPA to be used in order to receive accelerated parallel receive techniques. A multichannel transmit method is also conceivable with respect to transmission.

A proton magnetic resonance data record 3 and a sodium magnetic resonance data record 4 are consequently achieved as a result of the actual recording process. Differences in the resolution are provided here on account of the different K-space scannings for both core types due to the resulting difference in the scaling of the local frequencies, wherein the sodium magnetic resonance data record 4 has a resolution which is reduced four times so that the volume voxel there is greater by factor 64 than the voxel volume in the proton magnetic resonance data record 3. This is nevertheless advantageous in respect of the signal-to-noise ratio, which is limited in the sodium measurement.

In a step 5, an overall data record 6 should be determined by superimposing the proton magnetic resonance data record 3 and the sodium magnetic resonance data record 4, wherein the local assignment is possible without any problem on account of the calibration in step 1. An interpolation with the aid of spline functions is initially performed however in the sodium magnetic resonance data record 4, in order to adjust the local resolution, consequently therefore the voxel size, to the proton magnetic resonance data record 3. An improved representation of the overall data record 6 is therefore enabled. This is formed such that the proton magnetic resonance data record is represented with gray scale values, therefore in black and white, while the sodium magnetic resonance data can be shown as at least partially transparent color superimpositions on correct anatomical points. Variations in the sodium concentration can therefore be assigned to the details of the anatomy which is shown with a higher resolution.

The overall data record is finally shown in step 7, for instance layer by layer or in a three-dimensional representation.

FIG. 2 finally shows a magnetic resonance facility 8, which is suited to implementing the method. It includes, as known, a main field magnetic unit 9, in the boreholes of which a gradient coil arrangement 10 and a body coil arrangement 11 are provided and define a patient recording 12, into which a patient couch 13 can be introduced. A local coil 14 can be arranged on the patient couch 13, as close as possible to a patient to be examined, the coil elements of which (not shown here) can be wired in a double-resonant manner.

The magnetic resonance facility 8 further comprises a control facility, which is embodied to implement the method according to the application.

Although the application was illustrated and described in more detail by the exemplary embodiment, the application is therefore not restricted by the disclosed examples and other variations can be derived here from by the person skilled in the art without departing from the scope of protection of the application.

1. A method for recording magnetic resonance data with a magnetic resonance facility, comprising:
exciting both protons and sodium; and
recording a proton magnetic resonance data record and a sodium magnetic resonance data record during a single recording process.

2. The method as claimed in claim 1, wherein the proton magnetic resonance data record and the sodium magnetic resonance data record are each recorded in alternative recording cycles respectively.

3. The method as claimed in claim 2, wherein the proton magnetic resonance data record and the sodium magnetic resonance data record are each recorded in repetitive recording cycles respectively.

4. The method as claimed in claim 1, wherein the proton magnetic resonance data record and the sodium magnetic resonance data record are recorded in parallel, and wherein excitation pulses and receive times are used at a same time in recording.

5. The method as claimed in claim 1, wherein the magnetic resonance data is received by a receive coil for sodium signals and proton signals.

6. The method as claimed in claim 5, wherein the receive coil comprises a double-resonant receive coil or a coil element and is arranged in layers one above the other.

7. The method as claimed in claim 5, wherein at least one local coil is arranged on a patient as a transmit coil and/or receive coil.

8. The method as claimed in claim 5, wherein same gradient pulses and/or inversion pulses and/or erase pulses are simultaneously sent for the protons and the sodium.

9. The method as claimed in claim 1, wherein a same flow of a same gradient pulse is used during recording the proton magnetic resonance data record and the sodium magnetic resonance data record.

10. The method as claimed in claim 1, wherein a spatial calibration is implemented for a subsequent evaluation of the proton magnetic resonance data record and the sodium magnetic resonance data record.

11. The method as claimed in claim 10, wherein the spatial calibration is implemented based on a measurement on a phantom.

12. The method as claimed in claim 1, wherein the proton magnetic resonance data record and the sodium magnetic resonance data record are superimposed with each other and the superimposed data is displayed.

13. The method as claimed in claim 12, wherein the proton magnetic resonance data record is displayed in the superimposed data in gray scale values, and wherein the sodium magnetic resonance data record is superimposed onto the proton magnetic resonance data record in a colored and/or at least partially transparent representation.

14. The method as claimed in claim 12, wherein the sodium magnetic resonance data record is interpolated so that the interpolated sodium magnetic resonance data record has a same local resolution as the proton magnetic resonance data record for superimposition.

15. The method as claimed in claim 14, wherein the sodium magnetic resonance data record is interpolated by splines.

16. A magnetic resonance facility, comprising:
a control facility adapted to perform the method steps as claimed in claim 1.
